(19) United States
(12) Patent Application Publication
(10) Pub. No.: US 2016/0145734 A1
(43) Pub. Date: May 26, 2016

(54) PROTECTION FILM AND METHOD FOR DEPOSITING THE SAME

(71) Applicants: METAL INDUSTRIES RESEARCH & DEVELOPMENT CENTRE, Kaohsiung (TW); Chih-Ching HUANG, Kaohsiung City (TW)

(72) Inventors: Chih-Ching HUANG, KAOHSIUNG CITY (TW); Yu-Lin CHUNG, KAOHSIUNG CITY (TW); Sung-Mao CHIU, KAOHSIUNG CITY (TW); Ho-Chung FU, KAOHSIUNG CITY (TW)

(21) Appl. No.: 14/583,209

(22) Filed: Dec. 26, 2014

(30) Foreign Application Priority Data
Nov. 26, 2014 (TW) 103141046

(51) Int. Cl. C23C 14/14; C23C 14/24; C23C 14/58; C23C 14/34

(52) U.S. Cl. CPC C23C 14/14; C23C 14/34; C23C 14/24; C23C 14/5806

(57) ABSTRACT

A protection film and a method for depositing the protection film are provided. The method is used to form a protection film having low resistivity on a substrate. In the method, at first, a mixing operation is performed to mix a plurality of metal gases. The metal gases consist of silver, magnesium, and aluminum, or consist of silver, copper, and aluminum, or consist of copper, Nickel, and aluminum. The metal gases have two or more atom sizes. Thereafter, a depositing operation is performed to deposit an amorphous metal film on the substrate by using the mixed metal gases. The atoms of the amorphous metal film are arranged in a short-range order. Then an annealing treatment is performed to anneal the amorphous metal film to form a meta-stable metal film having averagely distributed grains to be used as the protection film.

### CROSS-REFERENCE TO RELATED APPLICATIONS

100011 This application claims priority to Taiwan Application Serial Number 103141046, filed Nov. 26, 2014, which is herein incorporated by reference.

### BACKGROUND

1. Field of Disclosure

The invention relates to a protection film and a method for depositing the same, and more particularly, to a protection film having low resistivity and a method for depositing the same.

2. Description of Related Art

As the electronic products are widely applied in human life, connectors of the electronic products have become more and more important. A connection terminal of a connector generally includes a conductive metal main body and a metal protection film covering the metal main body. The metal protection film is used to protect the metal main body from oxidation and wearing, so as to increase the operation life of the connector.

In a conventional connector, gold is generally used to fabricate the protection film of the connector due to its good conductivity and endurance. However, gold is expensive and a conventional gold plating process may generate hazardous wastes. Therefore, there is need to provide a protection film and a method for depositing the protection film to overcome the above problems.

### SUMMARY

The invention provides a protection film and a method for depositing the protection film. The protection film has low resistivity and cost of the protection film is lower than that of a conventional protection film.

In accordance with an embodiment of the present invention, the protection film consists of a plurality of metal materials. The metal materials are in a meta-stable state. An arrangement of atoms of the metal materials is in a short-range order. The metal materials consist of silver, magnesium, and aluminum, or consist of silver, copper, and aluminum, or consist of copper, nickel, and aluminum.

In accordance with another embodiment of the present invention, in the method for depositing the protection film, at first, a mixing operation is performed to mix a plurality of metal gases to obtain a mixed gas, in which of the metal gases have two or more atom sizes, and the metal gases consist of silver, magnesium, and aluminum, or consist of silver, copper, and aluminum, or consist of copper, nickel, and aluminum. Then, a depositing operation is performed to deposit an amorphous metal film on the substrate by using the mixed gases, in which an arrangement of atoms of the amorphous metal film is in a short-range order. Thereafter, an annealing treatment is performed on the amorphous metal film to form a meta-stable metal film having averagely distributed grains.

### BRIEF DESCRIPTION OF THE DRAWINGS

The disclosure can be more fully understood by reading the following detailed description of the embodiment, with reference made to the accompanying drawings as follows:

FIG. 1 is a schematic flow chart showing operations of a method for depositing a protection film in accordance with an embodiment of the present invention;

FIG. 2 is a schematic diagram showing an amorphous metal film formed on a substrate in accordance with an embodiment of the present invention;

FIG. 3a is a SEM (Scanning Electron Microscope) diagram of the amorphous metal film before annealing in accordance with an embodiment of the present invention;

FIG. 3b is a SEM diagram of the amorphous metal film after the annealing treatment in accordance with an embodiment of the present invention; and

FIG. 4 shows an XRD (X-Ray Diffraction) pattern of the amorphous metal film corresponding to different temperatures of the annealing treatment in accordance with an embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

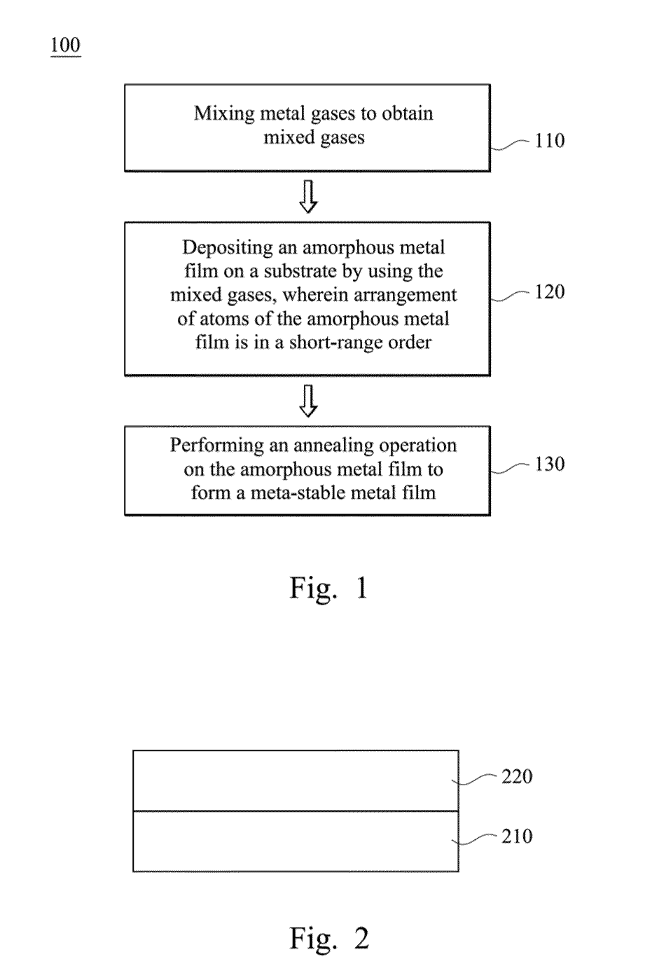

Referring to FIG. 1, FIG. 1 is a schematic flow chant showing operations of a method for depositing a protection film in accordance with an embodiment of the present invention. The method 100 is used to form the protection film on a metal main body of a connector to protect the metal main body. In the method 100, at first, an operation 110 is performed to provide plural metal gases (or referred to as metal materials), and to mix the metal gases to obtain mixed metal gas material used for deposition. In the embodiments of the present invention, the metal gases have two or more atom sizes. For example, in this embodiment, the metal gases consist of silver, magnesium, and aluminum, in which an atom size of silver is 1.6 angstroms (Å); an atom size of magnesium is 1.5 angstroms; an atom size of aluminum is about 1.25 angstroms.

In some embodiments of present invention, the metal gases consist of silver, copper, and aluminum, or consist copper, nickel, and aluminum, in which an atom size of copper and nickel is 1.35 angstroms.

After the operation 110, an operation 120 is performed to deposit an amorphous metal film 220 on a substrate 210 by using the mixed gases, as shown in FIG. 2. In this embodiment, the substrate 210 is used as a metal main body of terminals of a connector, and material of the substrate 210 can be copper, In some embodiments of the present embodiments, the substrate 210 further includes a median layer made of nickel, and the amorphous metal film 220 is formed on the median layer. Since the mixed gases of this embodiment have different atom sizes, atoms of the amorphous metal film 220 are arranged in a short-range order to avoid crystallization of the amorphous metal film 220.

In addition, in this embodiment, the operation 120 is performed by using a sputtering technology to form the amorphous metal film 220. However, embodiments of the present invention are not limited thereto. In some embodiments of the present invention, the operation 120 is performed by using an evaporation technology.

In order to form the amorphous metal film 220, the metal gases is mixed in accordance with proper percentages. For example, when the metal gases consist of silver, magnesium, and aluminum, an atomic percent (at %) of silver is between 30% and 50%, an atomic percent of magnesium is between 20% and 40%, and an atomic percent of aluminum is between 10% and 30%. For another example, when the metal gases consist of silver, copper, and aluminum, an atomic percent of silver is between 20% and 50%, an atomic percent of copper is between 20% and 50%, and an atomic percent of aluminum is between 10% and 30%. For another example, when the metal gases consist of copper, nickel, and aluminum, an atomic percent of copper is between 20% and 50%, an atomic percent of nickel between 20% and 50%, and an atomic percent of aluminum is between 10% and 30%.

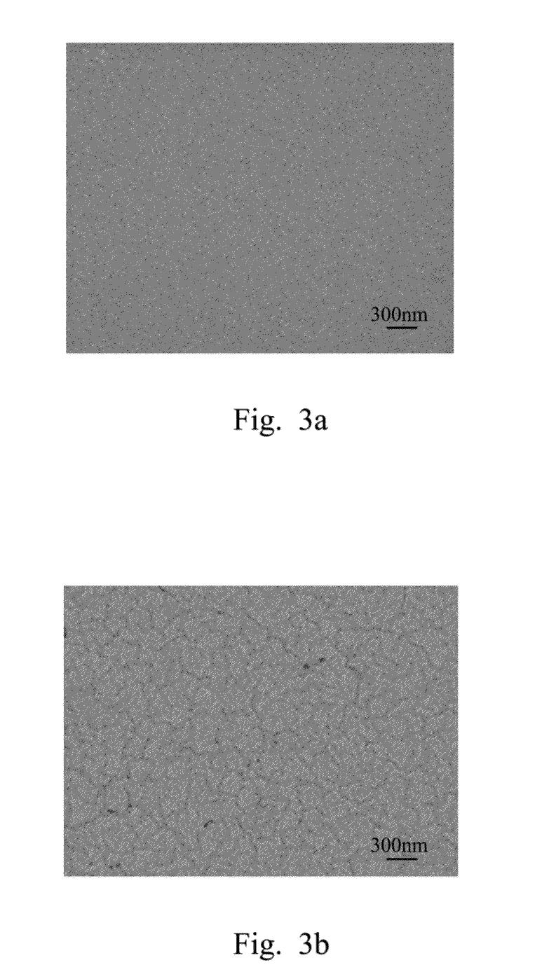

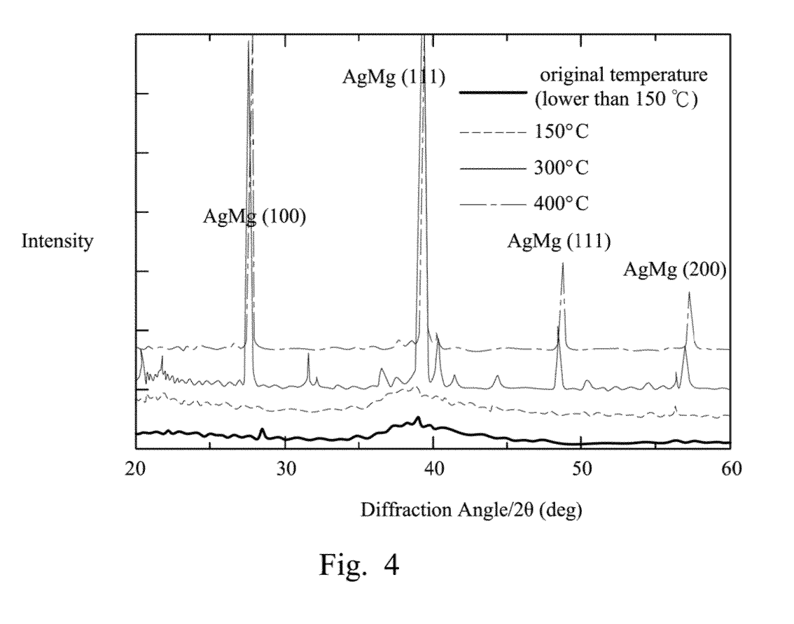

Thereafter, an operation 130 is performed to perform an annealing treatment on the amorphous metal film 220. In the operation 130, energy is provided to the amorphous metal film 220 through annealing treatment, such as rapid thermal annealing (RTA), to form a meta-stable metal film. The meta-stable metal film has averagely distributed micro grains, such that the resistivity of the meta-stable metal film is decreased. Referring to FIG. 3a and FIG. 3b, FIG. 3a is a SEM (Scanning Electron Microscope) diagram of the amorphous metal film 220 before annealing, and FIG. 3b is a SEM diagram of the amorphous metal film 220 after the annealing treatment. It can be understood from FIG. 3a and FIG. 3b that the amorphous metal film 220 has averagely distributed micro grains after the annealing treatment. The effect caused to the micro grains with regard to temperatures of the annealing treatment is shown as FIG. 4. FIG. 4 shows an XRD (X-Ray Diffraction) pattern of the amorphous metal film 220 treated at different temperatures of the annealing treatment, in which numbers in parentheses represent directions of the grains. It is understood from FIG. 4 that the annealing treatment enables the grains to grow and nucleate averagely, such that averagely distributed micro grains are formed in the meta-stable metal film formed after the annealing treatment to decrease the resistivty of the meta-stable metal film.

In this embodiment, the annealing treatment is performed at a temperature between about 200° C. and about 700° C. for about 5 to about 15 minutes. It is noted that the aforementioned operations 110-130 are performed in a vacuum environment to prevent the generation of impurities which will degrade the properties of the meta-stable metal film.

It can be understood that the method 100 of the embodiments of the present invention deposit the amorphous metal film on the substrate by using the metal gases selected from silver, magnesium aluminum, nickel, and copper, thereby forming the meta-stable metal film as a protection film to protect the terminals of the connecter. Since the meta-stable metal film has averagely distributed micro grains, the resistivity of the meta-stable metal film is low enough to meet the requirements for a protection film of a connector. Further, since the material of the meta-stable metal film is selected from silver, magnesium, aluminum, nickel, and copper, the cost of the meta-stable metal film is lower than that of the conventional protection film.

Although the disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims.

What is claimed is:

1. A protection film, consisting of:
a plurality of metal materials in a meta-stable state, wherein an arrangement of atoms of the metal materials is in a short-range order, and the metal materials consist of silver, magnesium, and aluminum, or consist of silver, copper, and aluminum, or consist of copper, nickel, and aluminum.

2. The protection film of claim 1, wherein when the metal materials consist of silver, magnesium, and aluminum, an atomic percent (at %) of silver is between 30% and 50%, an atomic percent of magnesium is between 20% and 40%, and an atomic percent of aluminum is between 10% and 30%.

3. The protection film of claim 1, wherein when the metal materials consist of silver, copper, and aluminum, an atomic percent of silver is between 20% and 50%, an atomic percent of copper is between 20% and 50%, and an atomic percent of aluminum is between 10% and 30%.

4. The protection film of claim 1, wherein when the metal materials are consist of copper, nickel, and aluminum, an atomic percent of copper is between 20% and 50%, an atomic percent of nickel is between 20% and 50%, and an atomic percent of aluminum is between 10% and 30%.

5. A method for depositing a protection lm on a substrate, the method comprising:
performing a mixing operation to mix a plurality of metal gases to obtain a mixed gas, wherein the metal gases have two or more atom sizes, and the metal gases consist of silver, magnesium, and aluminum, or consist of silver, copper, and aluminum, or consist of copper, nickel, and aluminum;
performing a depositing operation to deposit an amorphous metal film on the substrate by using the mixed gases, wherein an arrangement of atoms of the amorphous metal film is in a short-range order; and
performing an annealing treatment on the amorphous metal film to forma meta-stable metal film.

6. The method of claim 5, wherein the amorphous metal film is deposited on the substrate by using an evaporation technology or a sputtering technology, and the annealing treatment is performed at a temperature between 200° C. and 700° C. for 5 to 15 minutes.

7. The method of claim 5, wherein the mixing operation, the depositing operation, and the annealing treatment are performed in a vacuum environment.

8. The method of claim 5, wherein when the metal gases consist of silver, magnesium, and aluminum, an atomic percent of silver is between 30% and 50%, an atomic percent of magnesium is between 20% and 40%, and an atomic percent of aluminum is between 10% and 30%.

9. The method of claim 5, wherein when the metal gases consist of silver, copper, and aluminum, an atomic percent of silver is between 20% and 50%, an atomic percent of copper is between 20% and 50%, and an atomic percent of aluminum is between 10% and 30%.

10. The method of claim 5, wherein when the metal gases consist of copper, nickel, and aluminum, an atomic percent of copper is between 20% and 50%, an atomic percent of nickel is between 20% and 50%, and an atomic percent of aluminum is between 10% and 30%.
